(19) United States
(12) Patent Application Publication
(10) Pub. No.: US 2014/0060910 A1
(43) Pub. Date: Mar. 6, 2014

(54) CONNECTING APPARATUS AND PRINTED CIRCUIT BOARD THEREOF

(71) Applicants: HON HAI PRECISION INDUSTRY CO., LTD., New Taipei (TW); HONG FU JIN PRECISION INDUSTRY (ShenZhen) CO., LTD ., Shenzhen (CN)

(72) Inventors: Lin CHEN, Shenzhen (CN); Ying-Zheng WU, New Taipei (TW); Gua-Hua YUE, Shenzhen (CN); You-Chun QIAO, Shenzhen (CN)

(73) Assignees: HON HAI PRECISION INDUSTRY CO., LTD., New Taipei (TW); HONG FU JIN PRECISION INDUSTRY (ShenZhen) CO., LTD ., Shenzhen (CN)

(21) Appl. No.: 13/889,388

(22) Filed: May 8, 2013

(30) Foreign Application Priority Data
Aug. 28, 2012 (CN) 2012103093456

(51) Int. Cl. H05K 1/11

(52) U.S. Cl. CPC H05K 1/11
USPC 174/260

(57) ABSTRACT

A connecting apparatus for connecting a first electronic device and a second electronic device together comprises a first port, a second port electronically connected to the first port, and a printed circuit board (PCB). The PCB comprises a first grounded region, a second grounded region, and a first electronic element. The first electronic element is electronically connected between the first grounded region and the second grounded region. When the first electronic device is electronically connected to the second electronic device together via the connecting apparatus, the first port is electronically connected to the first electronic device, and the second port is electronically connected to the second electronic device. The first grounded region, the first electronic element, and the second grounded region form a first return current path for allowing high frequency signals to pass through. A printed circuit board thereof is also provided.

### BACKGROUND

1. Technical Field

The present disclosure relates to connecting apparatuses, particular relates to a connecting apparatus for electronically connecting two electronic devices.

2. Description of Related Art

A connecting apparatus for connecting a first electronic device with a second electronic device includes a printed circuit board (hereinafter, “PCB”). The first electronic device includes an antenna and a first grounded line, and the second electronic device includes a second grounded line. The PCB includes a grounded region. When the first electronic device is connected to the second electronic device via the connecting apparatus, the grounded region synchronously cooperates with the first grounded line and the second grounded line to form a returning current path. In design, for improving the antenna gain while the connecting apparatus transmits signals, the area of the grounded region needs to be decreased, but the electro-magnetic interference (EMI) of the connecting apparatus will be impaired.

Therefore, there is room for improvement in the art.

### BRIEF DESCRIPTION OF THE FIGURE

The components of the drawings are not necessarily drawn to scale, the emphasis instead being placed upon clearly illustrating the principles of the embodiment of a connecting apparatus. Moreover, in the drawings, like reference numerals designate corresponding parts throughout several views.

FIG. 1 is an isometric schematic view of a connecting apparatus with a PCB, according to an embodiment.

FIG. 2 is a schematic view of the PCB of FIG. 1.

FIG. 3 is block diagram of the connecting apparatus of FIG. 1.

### DETAILED DESCRIPTION

Embodiments of the present disclosure will be described in detail with reference to the drawings.

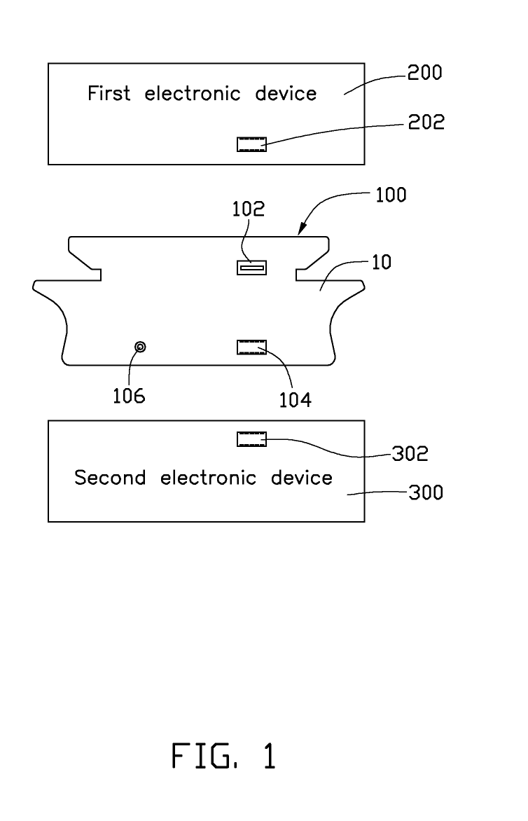

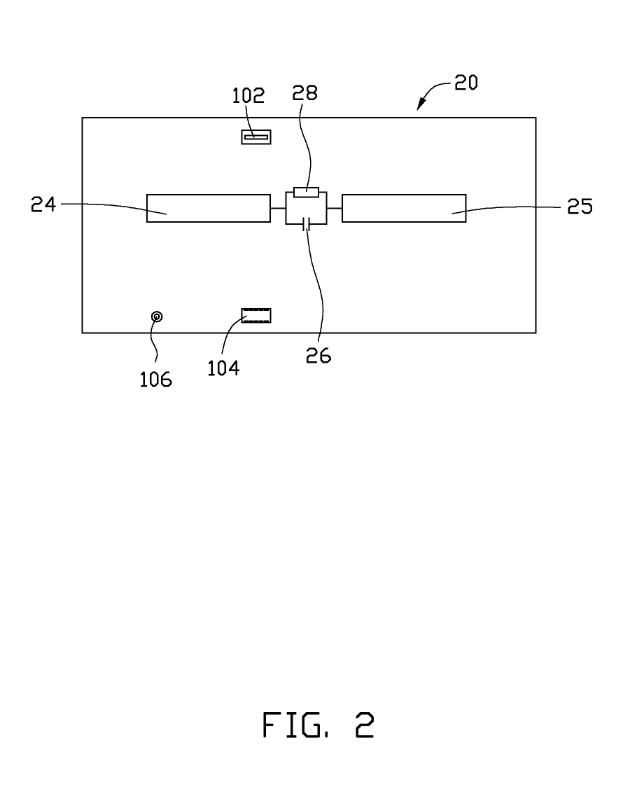

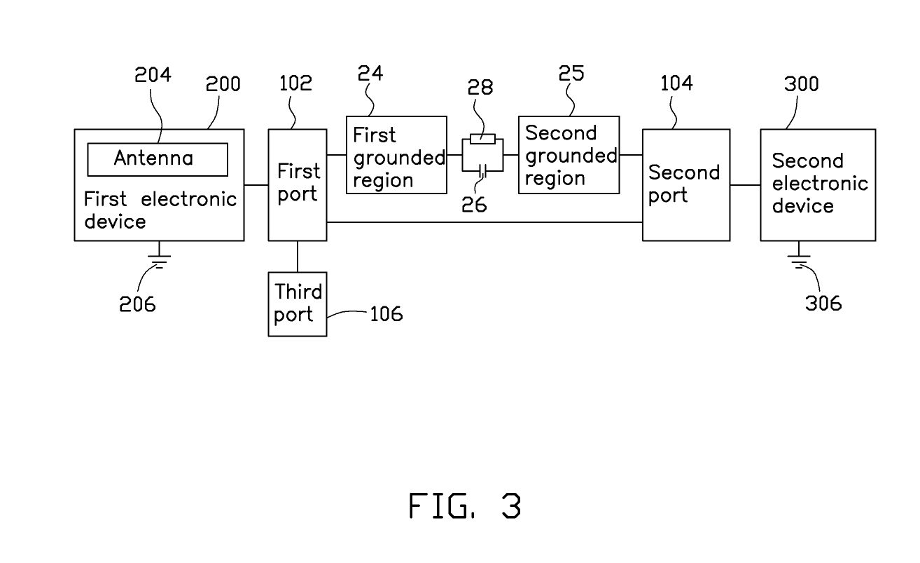

FIGS. 1 and 2 show a connecting apparatus 100 of the embodiment. The connecting apparatus 100 electronically connects a first electronic device 200 with a second electronic device 300 for transmitting data between the first electronic device 200 and the second electronic device 300. The first electronic device 200 with an antenna 204 (as shown in FIG. 3) includes a first external port 202 and a first grounded line 206 (as shown in FIG. 3). The second electronic device 300 includes a second external port 302 and a second grounded line 306 (as shown in FIG. 3). In the embodiment, the first electronic device 200 is a game machine; the second electronic device 300 is a computer; the first external port 202 and the second external port 302 are a USB type female connector. In other embodiments, the first electronic device 200 can be a power adaptor and is capable of charging the second electronic device 300 when being connected to the second electronic device 300.

The connecting apparatus 100 includes a housing 10, and a PCB 20 received in the housing 10. The housing 10 includes a first port 102, a second port 104, and a third port 106. In the embodiment, the first port 102, the second port 104, and the third port 106 are soldered on the PCB 20. In other embodiments, the first port 102, the second port 104, and the third port 106 are soldered on another PCB which is electronically connected to the PCB 20.

The first port 102 is electronically connected to the second port 104, and is coupled with the first external port 202 for electronically connecting the connecting apparatus 100 to the first electronic device 200. In the embodiment, the first port 102 is a USB type male connector.

The second port 104 is coupled with the second external port 302 for electronically connecting the connecting apparatus 100 to the second electronic device 300 by a cable (not shown). In the embodiment, the second port 104 is a USB type female connector.

The third port 106 receives audio signals from the first electronic device 200 and outputs the received audio signals through an inserted earphone (not shown). In the embodiment, the third port 106 is an earphone type female connector.

The PCB 20 includes a first grounded region 24, a second grounded region 25, a first electronic element 26, and a second electronic element 28. The first grounded region 24 and the second grounded region 25 are located on the surface of the PCB 20. The first electronic element 26 and the second electronic element 28 are soldered on the PCB 20 and connected in parallel between the first grounded region 24 and the second grounded region 25. The first electronic element 26 allows high frequency signals to pass through and prevents low frequency signals from passing through. The second electronic element 28 allows low frequency signals to pass through and prevents high frequency signal from passing through. In the embodiment, the first electronic element 26 is a capacitance, and the second electronic element 28 is a ferrite bead.

The first grounded region 24 is electronically connected to the first grounded line 206 via the first port 102, and the second grounded region 25 is electronically connected to the second grounded line 306 via the second port 104.

FIG. 3 shows that when the connecting apparatus 100 transmits high frequency signals between the first electronic device 200 and the second electronic device 300, the first grounded line 206, the first port 102, the first grounded region 24, the first electronic element 26, the second grounded region 25, the second port 104, and the second grounded line 306 form a first return current path. When the connecting apparatus 100 transmits low frequency signals between the first electronic device 200 and the second electronic device 300, the first grounded line 206, the first port 102, the first grounded region 24, the second electronic element 28, the second grounded region 25, the second port 104, and the second grounded line 306 form a second return current path. In the embodiment, the recited transmitted signals are digital signals. In other embodiments, the recited transmitted signals are analog signals; the first port 102, the second port 104, the first external port 202, the second external port 302 are a type of analog ports, such as VGA ports.

As described, because the first electronic element 26 and the second electronic element 28 connect in parallel between the first grounded region 24 and the second grounded region 25, both the EMI and the antenna gain of the connecting apparatus 100 are synchronously improved.

While various exemplary and preferred embodiments have been described, the disclosure is not limited thereto. On the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A connecting apparatus for connecting a first electronic device and a second electronic device together, the connecting apparatus comprising:
a first port;
a second port electronically connected to the first port; and
a printed circuit board (PCB);
wherein the PCB comprises a first grounded region, a second grounded region, and a first electronic element; the first electronic element is electronically connected between the first grounded region and the second grounded region; when the first electronic device is electronically connected to the second electronic device via the connecting apparatus, the first port is electronically connected to the first electronic device, and the second port is electronically connected to the second electronic device; the first grounded region, the first electronic element, and the second grounded region form a first return current path for allowing high frequency signals to pass through.

2. The connecting apparatus of claim 1, wherein the PCB further comprises a second electronic element; the first electronic element and the second electronic element electronically connect between the first grounded region and the second grounded region in parallel, the first grounded region, the second electronic element, and the second grounded region form a second return current path for allowing low frequency signals to pass through and preventing high frequency signals from passing through.

3. The connecting apparatus of claim 2, wherein the second electronic element is a ferrite bead.

4. The connecting apparatus of claim 1, wherein the first electronic element is a capacitance.

5. The connecting apparatus of claim 1, wherein the connecting apparatus further comprises a third port; the third port electronically connects with the first port and is used for receiving audio signals from the first electronic device.

6. The connecting apparatus of claim 5, wherein the first port, the second port, and the third port are soldered on the PCB.

7. The connecting apparatus of claim 1, wherein the first port is a USB type female connector and the second port is a USB type male connector.

8. The connecting apparatus of claim 1, wherein the high frequency signals are digital signals.

9. A printed circuit board (PCB) capable of electronically connecting first electronic device and a second electronic device together; the PCB comprising:
a first grounded region;
a second grounded region; and
a first electronic element;
wherein the first electronic element is electronically connected between the first grounded region and the second grounded region; when the first electronic device is electronically connected to the second electronic device via the PCB, the first grounded region, the first electronic element, and the second grounded region form a first return current path for allowing high frequency signals to pass through.

10. The PCB of claim 9, wherein the PCB further comprises a second electronic element; the first electronic element and the second electronic element electronically connect between the first grounded region and the second grounded region in parallel, the first grounded region, the second electronic element, and the second grounded region form a second return current path for allowing low frequency signals to pass through.

11. The PCB of claim 10, wherein the second electronic element is a ferrite bead.

12. The PCB of claim 9, wherein the first electronic element is a capacitance.

13. The PCB of claim 9, wherein the PCB further comprises a first port and a second port which are soldered on the PCB; the first port and the second port electronically connects with each other; the first port is used for electronically connecting with the first electronic device, and the second port is used for electronically connecting with the second electronic device.

14. The PCB of claim 13, wherein the first port is a USB type female connector and the second port is a USB type male connector.

15. The PCB of claim 9, wherein the high frequency signals are digital signals.
